(19) United States
(12) Patent Application Publication
(10) Pub. No.: US 2026/0301843 A1
(43) Pub. Date: Oct. 1, 2026

(54) ADAPTIVE MEDIA SCAN FOR ARC BIAS MANAGEMENT

(71) Applicant: Micron Technology, Inc., Boise, ID (US)

(72) Inventors: Li-Te Chang, San Jose, CA (US); Murong Lang, San Jose, CA (US); Dongxiang Liao, Cupertino, CA (US); Zhenming Zhou, San Jose, CA (US)

(21) Appl. No.: 19/089,828

(22) Filed: Mar. 25, 2025

(51) Int. Cl. G11C 29/52; G11C 29/02

(52) U.S. Cl. CPC G11C 29/52; G11C 29/022; G11C 2207/2254

(57) ABSTRACT

A system and method are provided for managing data on a memory device. The system and method perform a media scan operation on a portion of a memory device and determine one or more criteria associated with the portion of the memory device. The system and method adjust one or more folding conditions of the media scan operation based on the one or more criteria associated with the portion of the memory device and fold the portion of the memory device in response to determining that the adjusted one or more folding conditions are satisfied.

### TECHNICAL FIELD

This disclosure relates generally to memory sub-systems and, more specifically, to providing adaptive media management for memory components, such as memory dies.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various examples of the disclosure. The drawings, however, should not be taken to limit the disclosure to the specific examples, but are for explanation and understanding only.

FIG. 1 is a block diagram illustrating an example computing system that includes a memory sub-system, in accordance with some examples.

FIG. 2 illustrates a read window budget (RWB) diagram and differential and center error computations, in accordance with some examples.

FIG. 3 illustrates a routine performed using the media operations manager, in accordance with some examples.

FIG. 4 illustrates a routine performed using the media operations manager, in accordance with some examples.

FIG. 5 illustrates a lookup table for a predetermined voltage offset, in accordance with some examples.

FIG. 6 illustrates a routine performed using the media operations manager, in accordance with some examples.

FIG. 7 is a block diagram of an example computer system, in accordance with some examples.

### DETAILED DESCRIPTION

The present disclosure configures a memory sub-system controller to adaptively adjust folding conditions during media scan operations to prevent unnecessary block folding. Specifically, when performing a media scan operation on a portion of the memory device, the controller first obtains a fail bit count (also referred to as a bit error count (BEC) or bit error rate (BER)) from a default read (e.g., by performing a read operation on the portion using a default threshold voltage). If the fail bit count exceeds a threshold value, the controller performs a valley health check (VHC) that obtains a differential error count and center error count. The controller then determines whether to fold a block containing the portion based on one or more folding conditions. The folding conditions can include or be based on a first folding condition that includes the differential error count (DiffEC) and a second folding condition that includes the center error count (CenterEC). The controller can selectively bypass the first folding condition for predetermined weak word lines (WLs) and fold the portion when the second folding condition is satisfied or met. In some cases, the controller can adjust the first folding condition, such as by adjusting the predetermined voltage offset (e.g., automatic gain control (AGC)) based on the page type and word line group (WLG) used to compute the DiffEC. If the selected folding conditions are satisfied in the media scan operation, then the controller can fold the portion of the memory device. This adjustment of the folding conditions (including bypassing certain folding conditions) helps prevent overfolding of healthy blocks by accounting for automatic read calibration (ARC) bias that can cause unbalanced left and right error counts. This can reduce unnecessary block folding operations while maintaining reliability through periodic background media scanning to preserve enough margin for unexpected power loss.

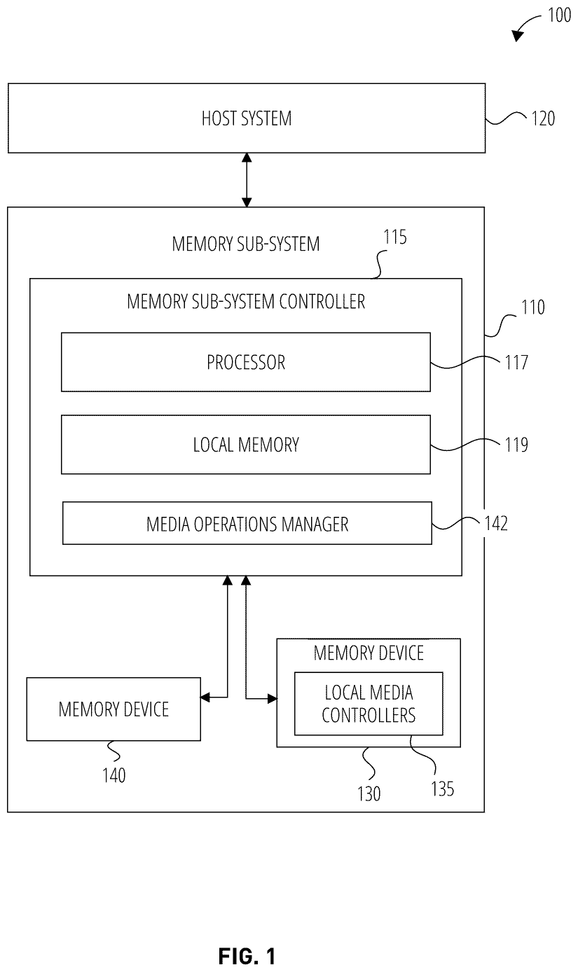

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data.”

The memory sub-system can initiate media management operations, such as a write operation, on host data that is stored on a memory device. In some examples, firmware of the memory sub-system may rewrite previously written host data from a location on a memory device to a new location as part of garbage collection management operations. The data that is rewritten, for example as initiated by the firmware, is hereinafter referred to as “garbage collection data”. “User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction code (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest area that can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND, mNAND), which are raw memory device combined with a local embedded controller for memory management within the same memory device package.

Media scan is an important feature in solid state drives (SSDs) that performs periodic background scanning across the entire drive to preserve enough reliability margin for unexpected power loss. The main purpose is to ensure that if a drive suddenly turns off and remains off for an extended period (e.g., one year), the data can still be recovered without uncorrectable errors when power is restored.

Conventional media scan approaches use a multi-step process that can be inefficient and waste resources. First, conventional media scan operations perform a default read of each page to obtain a fail bit count. If this fail bit count exceeds a threshold, the conventional media scan operations trigger a VHC that uses ARC offsets to find the valley bottom (e.g., in multi-level cell storage, such as tri-level cell (TLC) memory). The VHC then collects left and right error counts using both the ARC offset and a predetermined voltage offset, such as an automatic gain control (AGC) offset, to compute a differential error count. If this differential error count exceeds a threshold value, the entire block containing that page is folded (rewritten).

However, this conventional approach is inefficient because the ARC process has an inherent bias. The ARC process does not necessarily find the true center of the valley but instead can be located too far to the left side of the center of the valley or too far to the right side of the center of the valley. This bias leads to unbalanced left and right error counts, which in turn can cause the differential error count to be artificially high. As a result, the conventional media scan algorithm can end up triggering unnecessary block folding operations on otherwise healthy blocks. Each folding operation forces the host to put operations on hold and introduces significant latency, wasting system resources and degrading overall SSD performance.

The present disclosure addresses these technical challenges in memory systems by providing a memory sub-system controller that adaptively adjusts folding conditions during media scan operations to prevent unnecessary block folding. The controller performs a default read operation to obtain a fail bit count and, if the fail bit count exceeds a threshold value, executes a valley health check to obtain differential and center error counts. Based on the characteristics of the portion being read, such as page type and word line group, the controller either bypasses the differential error count threshold check for predetermined weak word lines and uses only the center error count threshold, and/or adjusts the predetermined voltage offset (e.g., the AGC offset) using values from a lookup table before performing the threshold checks (e.g., the folding conditions, which test whether the DiffEC and/or the CenterEC exceed corresponding thresholds) to trigger folding operations. This selective application of adjusted folding conditions prevents overfolding of healthy blocks by accounting for ARC bias that can cause unbalanced left and right error counts, thereby maintaining reliability while reducing unnecessary block folding operations that degrade system performance.

In some examples, a system that includes a memory device and a processing device operatively coupled to the memory device is provided. In some examples, the processing device performs a media scan operation on a portion of the memory device to preserve enough reliability margin for unexpected power loss. The processing device determines one or more criteria associated with the portion, such as whether the portion includes word lines that are predetermined as weak word lines during manufacturing.

In some circumstances, the processing device performs a default read operation on the portion to compute a bit error count. When this count exceeds a threshold value, the processing device performs a valley health check that involves obtaining an automatic read calibration offset and a predetermined voltage offset. The valley health check generates a differential error count and center error count by reading data using voltages computed based on these offsets. In some implementations, obtaining the automatic read calibration offset involves generating multiple histograms from reading the portion, performing a coarse calibration to obtain an initial read level, and then performing fine calibration. The fine calibration determines slopes based on the read level, computes a calibration step value by comparing the slopes, and adjusts the read level to obtain the final offset.

In some cases, the differential error count is computed by obtaining left and right error counts. The left error count is obtained by reading with a voltage that adds a negative automatic gain control offset to the automatic read calibration offset, while the right error count uses a positive offset. The center error count is obtained by reading with just the automatic read calibration offset.

In some examples, the processing device adjusts folding conditions by either bypassing differential error count checks for predetermined weak word lines and using only the center error count, or by selecting the predetermined voltage offset based on the page type and word line group of the portion from a lookup table. The page types may include extra pages, upper pages, or lower pages. The lookup table may store different predetermined voltage offset values indexed by page type and word line group.

In some implementations, the folding conditions involve comparing the differential error count to a first threshold and the center error count to a second threshold. When the adjusted folding conditions are satisfied, the processing device folds the portion by rewriting data from a block containing the portion to a different block. The criteria used for adjustment are determined during the valley health check, which measures characteristics like valley width and depth. In some examples, this adaptive approach is implemented in a three-dimensional NAND memory device.

The system can also be implemented as a method or stored as instructions on a non-transitory machine-readable storage medium that, when executed, cause a processing device to perform these operations.

Though various examples are described herein as being implemented with respect to a memory sub-system (e.g., a controller of the memory sub-system), some or all of the portions of an embodiment can be implemented with respect to a host system, such as a software application or an operating system of the host system.

FIG. 1 illustrates an example computing system 100 that includes a memory sub-system 110, in accordance with some examples. The memory sub-system 110 can include media, such as one or more volatile memory devices (e.g., memory device 140), one or more non-volatile memory devices (e.g., memory device 130), or a combination of such.

In some examples, the memory device 130, including one or more portions (e.g., one or more WLs, one or more WL groups (WLGs), one or more blocks, one or more memory dies, and/or one or more pages) or group of memory components including the memory device 130, can be associated with a first reliability (capability) grade, value, measure, or lifetime program-erase count (PEC). The terms “reliability grade,” “value,” and “measure” are used interchangeably throughout and can have the same meaning. The memory device 140 (e.g., one or more WLs, one or more WLGs, one or more blocks, one or more memory dies, and/or one or more pages) or group of memory components, including the memory device 140, can be associated with a second reliability (capability) grade, value, measure, or lifetime PEC. In some examples, each memory component (memory device 130 and memory device 140) can store respective configuration data that specifies the respective reliability grade and lifetime PEC and current PEC and/or other conditions. In some examples, a memory or register can be associated with all of the memory components (memory device 130 and memory device 140) and can store a table that maps different groups, portions, bins, or sets of the memory device 130 and memory device 140 to respective reliability grades, conditions, lifetime PEC values, and/or current PEC values.

A memory sub-system 110 can be a storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some examples, the host system 120 is coupled to different types of memory sub-systems 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., NVDIMM controller), and a storage protocol controller (e.g., a peripheral component interconnect express (PCIe) controller, serial advanced technology attachment (SATA) controller). The host system 120 uses the memory sub-system 110, for example, to write data to the memory sub-system 110 and read data from the memory sub-system 110.

The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory devices 130, 140 when the memory sub-system 110 is coupled with the host system 120 by the PCIe or CXL interface. The physical host interface can provide an interface for passing control, address, data, and other signals between the memory sub-system 110 and the host system 120.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a NAND flash memory and write-in-place memory, such as a 3D cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional (2D) NAND and 3D NAND.

Each of the memory devices 130, 140 can include one or more arrays of memory cells. One type of memory cell, for example, single level cells (SLCs), can store one bit per cell. Other types of memory cells (e.g., including multi-level cell storage), such as multi-level cells (MLCs), tri-level cells (TLCs), quad-level cells (QLCs), and penta-level cells (PLCs), can store multiple bits per cell. In some examples, each of the memory devices 130, 140 can include one or more arrays of memory cells such as SLCs, MLCs, TLCs, QLCs, or any combination of such. In some examples, a particular memory device can include an SLC portion, and an MLC portion, a TLC portion, or a QLC portion of memory cells. The memory cells of the memory devices 130, 140 can be grouped as pages that can refer to a logical unit of the memory device used to store data. With some types of memory (e.g., NAND), pages can be grouped to form blocks or block stripes (BSs). As used herein, a block comprising SLCs can be referred to as a SLC block, a block including MLCs can be referred to as an MLC block, a block comprising TLCs can be referred to as a TLC block, and a block comprising QLCs can be referred to as a QLC block.

Although non-volatile memory components such as NAND-type flash memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide-based RRAM (OxRAM), negative-or (NOR) flash memory, and electrically erasable programmable read-only memory (EEPROM).

A memory sub-system controller 115 (or controller 115 for simplicity) can communicate with the memory devices 130, 140 to perform operations such as reading data, writing data, or erasing data (e.g., performing garbage collection (GC) operations) at the memory devices 130, 140 and other such operations. The memory sub-system controller 115 can include hardware such as one or more integrated circuits and/or discrete components, a buffer memory, or a combination thereof. The hardware can include digital circuitry with dedicated (e.g., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some examples, the local memory 119 can include memory registers storing memory pointers, fetched data, and so forth. The local memory 119 can also include ROM for storing micro-code. While the example memory sub-system 110 in FIG. 1 has been illustrated as including the memory sub-system controller 115, in another example, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, GC operations, error detection and ECC operations, encryption operations, caching operations, and address translations between a logical address (e.g., logical block address (LBA), namespace) and a physical memory address (e.g., physical block address in a physical address space of the memory device 130 or memory device 140) that are associated with the memory devices 130, 140. The memory sub-system controller 115 can further include host interface circuitry to communicate with the host system 120 via the physical host interface. The host interface circuitry can convert the commands received from the host system 120 into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some examples, the memory sub-system 110 can include a cache or buffer (e.g., DRAM) and address circuitry (e.g., a row decoder and a column decoder) that can receive an address from the memory sub-system controller 115 and decode the address to access the memory devices 130, 140.

In some examples, the memory device 130 includes local media controllers 135 that operate in conjunction with memory sub-system controller 115 to execute operations on one or more memory cells of the memory device 130. An external controller (e.g., memory sub-system controller 115) can externally manage the memory device 130 (e.g., perform media management operations on the memory device 130). In some examples, a memory device 130 is a managed memory device, which is a raw memory device combined with a local controller (e.g., local media controller 135) for media management within the same memory device package. An example of a managed memory device is a managed NAND (mNAND) device. Any operation discussed as being performed by the memory sub-system controller 115 can be similarly performed by the local media controllers 135 and vice versa.

The media operations manager 142 can perform adaptive media scan operations to prevent unnecessary block folding in memory devices 130. Specifically, when performing a media scan operation on a portion (e.g., a page, WL, WLG, memory block, and so forth) of the memory device 130, the media operations manager 142 first performs a default read operation, which involves reading the page (or portion of the memory device 130) with default threshold voltage settings to obtain a fail bit count (also referred to as a bit error count (BEC) or bit error rate (BER)). This default read serves as an initial screening mechanism, such as that if the fail bit count is below a threshold value, indicating the page is healthy, the media operations manager 142 moves on to scan the next page or portion. However, if the fail bit count exceeds the threshold value, the media operations manager 142 triggers a deeper analysis through a VHC to obtain differential and center error counts.

The default read operation represents the first level of screening in the media scan process, using standard read parameters before applying any calibration or offset adjustments. This approach allows the system to quickly identify pages that are functioning normally without needing to perform more complex and time-consuming valley health checks. The fail bit count from this default read provides a baseline measurement of the page's health and determines whether further analysis is needed.

During the VHC, the media operations manager 142 obtains an ARC offset. For example, the media operations manager 142 can generate multiple histograms from reading the portion, performing coarse calibration to get an initial read level, and then conducting fine calibration. The fine calibration process involves determining slopes based on the read level, computing a calibration step value by comparing the slopes, and adjusting the read level to obtain the final offset.

For example, when reading a 16 kB page, the media operations manager 142 counts one bit per byte to generate these histograms. After obtaining the histograms, the media operations manager 142 performs coarse calibration to determine an initial read level (ra). For instance, if the “111” value is greater than the “110” value, the media operations manager 142 sets the optimal read level to “rb”. Alternatively, if the “111” value is greater than both “101” and “110” values, the media operations manager 142 sets the optimal read level to “ra”. “ra” and “rb” refer to different read levels determined during the coarse calibration phase of the ARC process.

The fine calibration process then refines this initial read level by analyzing slope relationships. The media operations manager 142 determines two slopes (SP1 and SP2) based on the initial read level. For example, when SP1 is approximately equal to SP2, the final read level remains at ra. However, when SP1 is significantly larger than SP2, the media operations manager 142 adjusts the read level by adding a certain number of times (e.g., 9 times) the calibration step value to ra to obtain rc. The calibration step value itself is computed based on comparing these slopes, with the arc_gap_tlc being set to 90 mV and the step calculated as gap/9. This calibration process aims to find the optimal read level as the ARC offset, though it may sometimes result in ARC bias where E13 becomes significantly larger than E12 due to valley asymmetry, as discussed below.

The media operations manager 142 can then use this ARC offset along with the predetermined voltage offset (e.g., AGC offset) to compute error counts. For example, when reading an extra page (XP), the media operations manager 142 reads level 3 and level 7 of the TLC memory, applying the calibrated ARC offset to center the read level and then adding positive and negative AGC offsets to obtain right and left error counts respectively.

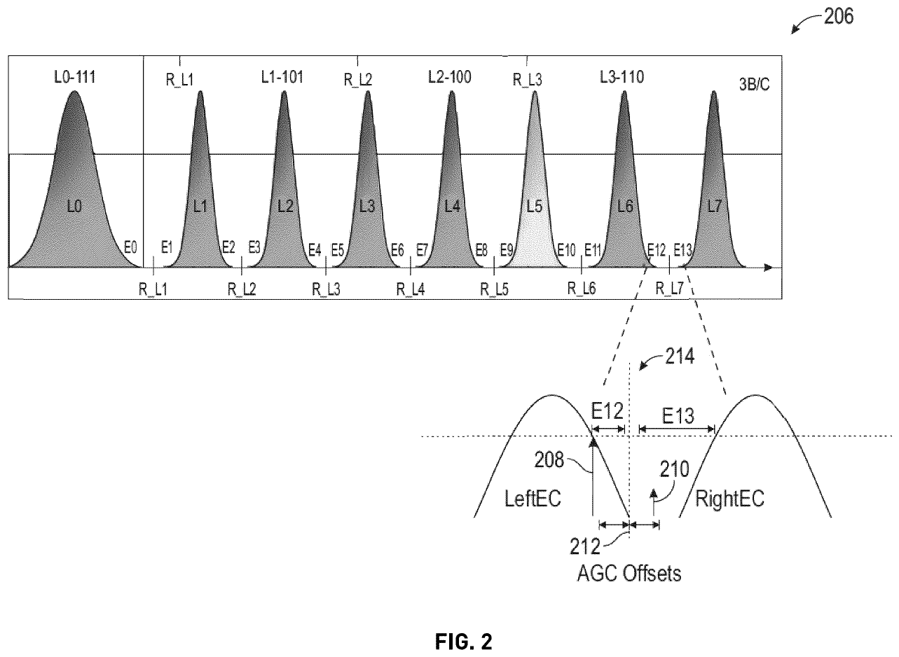

For example, FIG. 2 illustrates how the media operations manager 142 computes error counts (e.g., CenterEC and DiffEC) using both the ARC offset and AGC offset. FIG. 2 shows multiple read levels 206 representing different voltage thresholds used for reading TLC memory cells. These can include levels 0 through level 7 of the TLC memory.

In the valley region (e.g., the valley 214) between level 6 and level 7, the media operations manager 142 obtains a left error count 208 (LeftEC) by reading the valley 214 (e.g., associated with level 7) with a voltage that combines the ARC offset with a negative AGC offset. Similarly, the media operations manager 142 obtains a right error count 210 (RightEC) by reading the valley 214 associated with level 7 with a voltage that adds a positive AGC offset to the ARC offset. The differential error count (DiffEC) is then computed as the average of these left and right error counts. In an ideal balanced case, these error counts would be similar, indicating the read level is properly centered in the valley. However, when ARC bias occurs, it can result in unbalanced error counts where one side (E12 or E13) is significantly larger than the other.

In the valley 214, the error counts represent the number of bits that are read incorrectly when using specific threshold voltages. When performing a read operation, the media operations manager 142 applies different voltage thresholds to read the data. Specifically, the media operations manager 142 uses a voltage that combines the ARC offset with a negative AGC offset to obtain the left error count 208 (LeftEC), and a voltage that adds a positive AGC offset to the ARC offset to obtain the right error count 210 (RightEC). For each read operation, the media operations manager 142 counts the number of bits that are read incorrectly using that particular threshold voltage. For example, when reading an extra page (XP), the system reads level 3 and level 7, applying these different voltage thresholds and counting the number of bit errors that occur at each threshold. The left error count 208 represents the number of bits read incorrectly using the negative offset voltage, while the right error count 210 represents the number of bits read incorrectly using the positive offset voltage.

In an ideal balanced case where the read level is properly centered in the valley, these error counts 208, 210 would be similar on both sides. However, when ARC bias occurs, it can result in unbalanced error counts where significantly more bit errors are detected on one side compared to the other (E12 or E13). This imbalance indicates that the read threshold is not optimally positioned in the center of the valley 214.

The center error count 212 can be computed by reading the portion of memory using only the ARC offset, without applying any AGC offset. This represents the error count at the valley bottom after ARC calibration has positioned the read level. The center error count 212 provides a measure of the valley depth, while avoiding the potential bias introduced by the AGC offsets used for left and right error counts. When the ARC process finds the true valley center, this center error count 212 may represent the minimum error rate achievable for that portion of memory. However, due to ARC bias, the read level may not be perfectly centered, resulting in a center error count 212 that could be higher than optimal even though the valley 214 itself is healthy.

The AGC offsets, shown at the bottom of the valley diagram, represent the predetermined voltage adjustments applied relative to the ARC offset to obtain the left and right error counts 208, 210. As discussed below, in some cases, these offsets can be tuned based on the page type and word line group to help compensate for ARC bias.

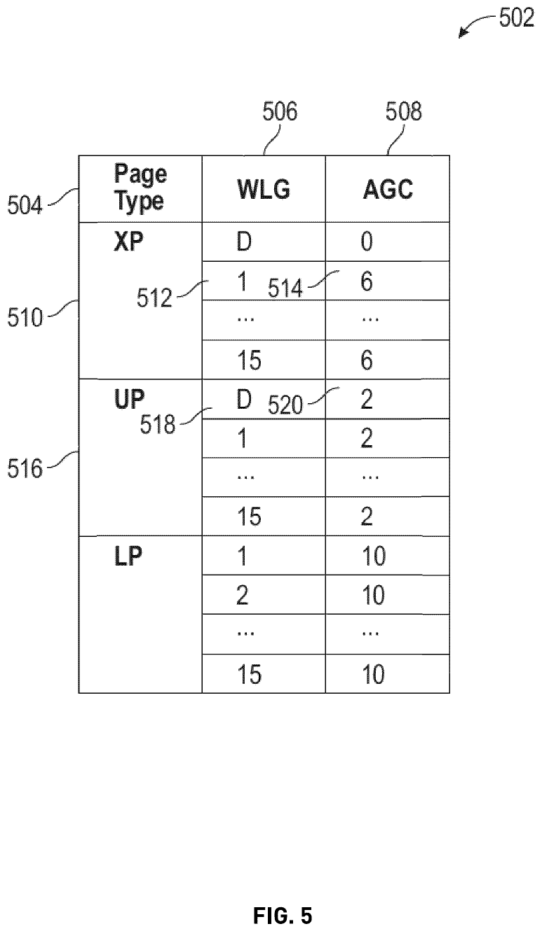

By carefully selecting appropriate AGC offset values from a lookup table (e.g., lookup table 502 of FIG. 5) based on the page characteristics (e.g., one or more criteria of a portion on which the media scan operation is being performed), the media operations manager 142 can better account for valley asymmetry and avoid unnecessary folding operations.

In some cases, the media operations manager 142 can determine whether to fold the portion (e.g., a memory block) based on one or more folding conditions. The folding conditions can include a first folding condition that triggers folding of the portion based on comparing the differential error count to a first threshold value. The folding conditions can include a second folding condition that triggers folding of the portion based on comparing the center error count to a second threshold value. For predetermined weak word lines, the media operations manager 142 can bypass the first folding condition in which the differential error count threshold check is performed and only folds the portion or the memory block containing the portion based on the second folding condition.

For other word lines, both folding conditions can be considered and used to trigger folding of the portion or memory block containing the portion. In some cases, both the first and the second folding conditions need to be satisfied to trigger the folding operation of the memory block or portion. In some cases, the memory block or portion is folded if either the first or the second folding condition is satisfied (e.g., the differential error count exceeds the first threshold value and/or the center error count exceeds the second threshold value). In some cases, the media operations manager 142 can adjust the predetermined voltage offset (e.g., the AGC offset) that is used to compute the DiffEC (relied upon to determine whether the first folding condition is satisfied) based on the page type and word line group. This can be performed using values from a lookup table before performing threshold comparisons of the first/second folding conditions. This selective application of folding conditions helps prevent unnecessary folding operations on healthy blocks while maintaining reliability through periodic background scanning.

Namely, the media operations manager 142 can apply any one or combination of two approaches to improve selective folding of memory blocks in the media scan operations. In a first approach, the media operations manager 142, for predetermined weak word lines identified during manufacturing, bypasses checking if the differential error count exceeds its threshold and only uses the center error count threshold. This prevents false folding triggers caused by automatic read calibration bias on these known weak word lines. In the second approach, the media operations manager 142 adjusts the AGC offset used to compute the differential error count based on the page type and word line group of the portion being read. The media operations manager 142 maintains a lookup table that stores different predetermined voltage offset values indexed by page type (such as extra pages, upper pages, or lower pages) and word line group. The media operations manager 142 uses that lookup table to select the AGC offset that is used in the second approach to compute the DiffEC for a portion being read in the media scan operation.

By selectively applying these adjusted folding conditions, the media operations manager 142 prevents overfolding of healthy blocks that can occur due to automatic read calibration bias causing unbalanced left and right error counts. This adaptive approach maintains reliability through periodic background scanning while reducing unnecessary block folding operations that would otherwise degrade system performance.

The media operations manager 142 implements these operations as part of the memory sub-system controller 115's overall management of the memory devices 130. The memory sub-system controller 115 can be configured to perform these operations on various types of memory devices, including three-dimensional NAND devices. This approach particularly benefits SSDs by preserving enough reliability margin for unexpected power loss without triggering excessive folding operations.

Any discussion with respect to the memory device 130 can similarly be applied to the memory device 140. Any function pertaining to the local media controllers 135 can, in some cases, be performed by the memory sub-system controller 115.

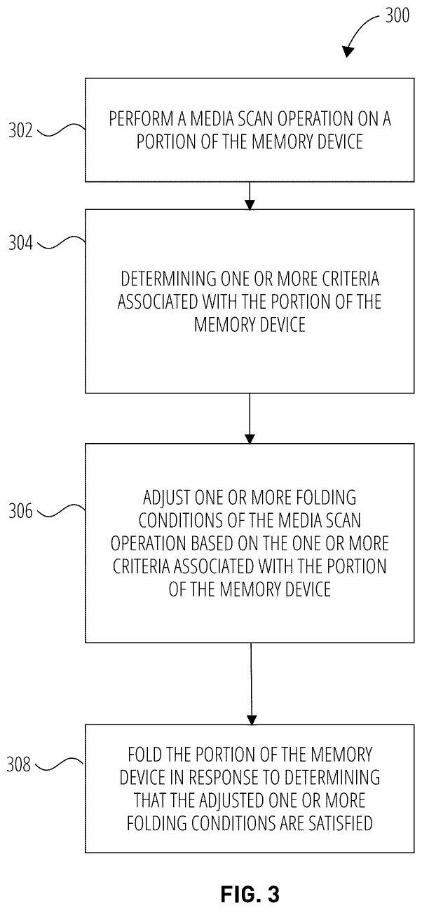

FIG. 3 illustrates a routine 300 of operations performed using the media operations manager 142, in accordance with some examples. The method or process of routine 300 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of routine 300 is performed by the memory sub-system controller 115, local media controllers 135, and/or subcomponents of the memory sub-system controller 115 and/or local media controllers 135 of FIG. 1. In these examples, the method or process of routine 300 can be performed, at least in part, by the media operations manager 142. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example. Other process flows are possible.

The routine 300 begins at operation 302 with the media operations manager 142 performing a media scan operation on a portion of the memory device 130 to preserve enough reliability margin for unexpected power loss. At operation 304, the media operations manager 142 determines one or more criteria associated with the portion, such as whether it includes predetermined weak word lines or its page type and word line group.

Then, at operation 306, the media operations manager 142 adjusts one or more folding conditions based on the determined criteria. For predetermined weak word lines, this involves bypassing the differential error count threshold check and using only the center error count threshold. For other portions, this involves adjusting the AGC offset based on the page type and word line group using values from the lookup table 502, discussed below.

At operation 308, the media operations manager 142 folds the portion by rewriting data from a block containing the portion to a different block, but only if the adjusted folding conditions are satisfied. This selective application of adjusted folding conditions helps prevent overfolding of healthy blocks while maintaining reliability through periodic background scanning.

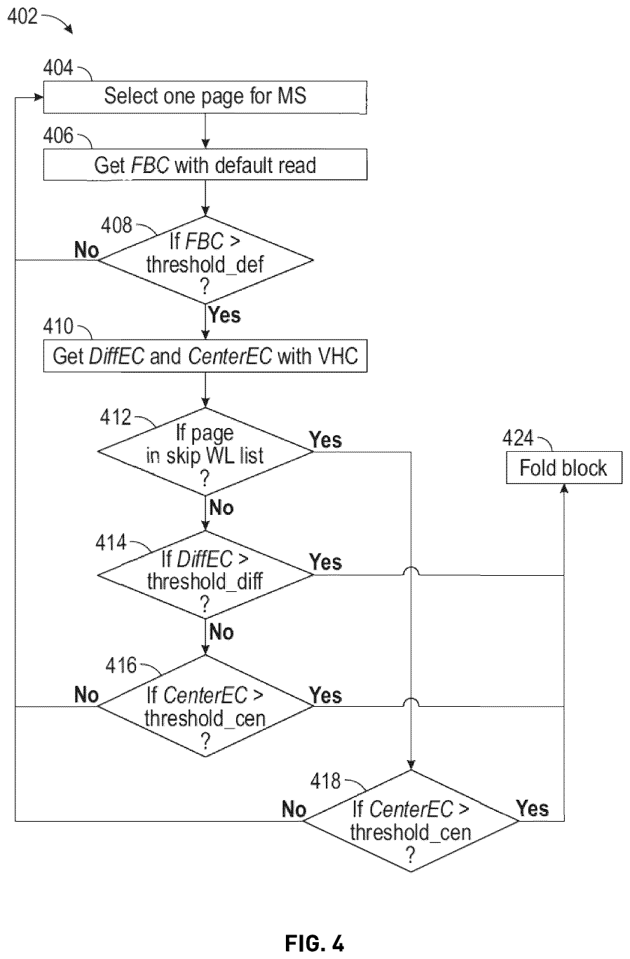

FIG. 4 illustrates a routine 402 performed by the media operations manager 142 to implement the first approach of the adaptive media scan operations, in accordance with some examples. The routine 402 can be performed by processing logic including hardware (e.g., processing devices, circuitry, dedicated logic, programmable logic, microcode, integrated circuits) and/or software executed by the media operations manager 142.

The routine 402 begins at operation 404 where the media operations manager 142 selects a page (e.g., a portion of the memory device 130) for media scan. At operation 406, the media operations manager 142 performs a default read to obtain a fail bit count (FBC) or BEC. At operation 408, the media operations manager 142 determines if the FBC exceeds a threshold value (threshold_def).

If the FBC exceeds the threshold, the media operations manager 142 performs operation 410. At operation 410, the media operations manager 142 performs a VHC to obtain differential error count (DiffEC) and center error count (CenterEC) for the page (or portion), such as using the ARC offset and the AGC offset. At operation 412, the media operations manager 142 checks if the page or portion being read is in a predetermined list of weak word lines. If the page is in the weak word line list, the media operations manager 142 proceeds directly to operation 418 to check only if the CenterEC exceeds its threshold (threshold_cen). If the page is not in the weak word line list (as determined in operation 412), the media operations manager 142 performs operation 414 to check if the DiffEC exceeds its threshold (threshold_diff).

If either the DiffEC threshold check at operation 414 or CenterEC threshold check at operation 416 and/or operation 418 is satisfied (either folding conditions is met), the media operations manager 142 proceeds to operation 424 to fold the block that includes the portion or page; otherwise the process returns to operation 404. This selective application of folding conditions helps prevent unnecessary folding of healthy blocks while maintaining reliability through periodic background scanning.

The routine 402 can be modified to perform operations in different orders or in parallel, and some operations may be omitted in various implementations. The method provides an adaptive approach that accounts for automatic read calibration bias while preserving enough margin for unexpected power loss.

FIG. 5 illustrates a lookup table for a predetermined voltage offset, in accordance with some examples. Namely, FIG. 5 illustrates a lookup table 502 that stores predetermined voltage offset values used during the media scan operation's VHC process. The lookup table 502 includes three main columns: a page type column 504, a word line group (WLG) column 506, and an automatic gain control (AGC) offset column 508.

The page type column 504 of the lookup table 502 lists different types of pages that can be accessed during the media scan operation. The first page type 510 shown is an extra page (XP), followed by entries for upper pages (UP) and lower pages (LP). For the XP page type, the lookup table 502 shows multiple WLG entries starting with WLG 0 and WLG 1, continuing through WLG 15. Each WLG entry corresponds to a specific AGC offset value, for example, a first WLG 512 for the first page type 510 has a first predetermined voltage offset 514 (e.g., an AGC offset of 6), while WLG 1 has an offset of 6.

The UP page type section (e.g., second page type 516) of the entries of lookup table 502 shows a different pattern of AGC offsets, with WLG 0 having an AGC offset of 2. This pattern continues through WLG 15, maintaining a consistent AGC offset of 2 for all UP page WLGs. For example, a second WLG 518 for the entries for the second page type 516 has a second predetermined voltage offset 520 (e.g., an AGC offset of 2), and WLG 1 has an offset of 2. For the LP page type of entries, the lookup table 502 shows yet another pattern, with all WLGs using a larger AGC offset value of 10. This demonstrates how the AGC offset values are customized based on both the page type and WLG to account for different valley characteristics.

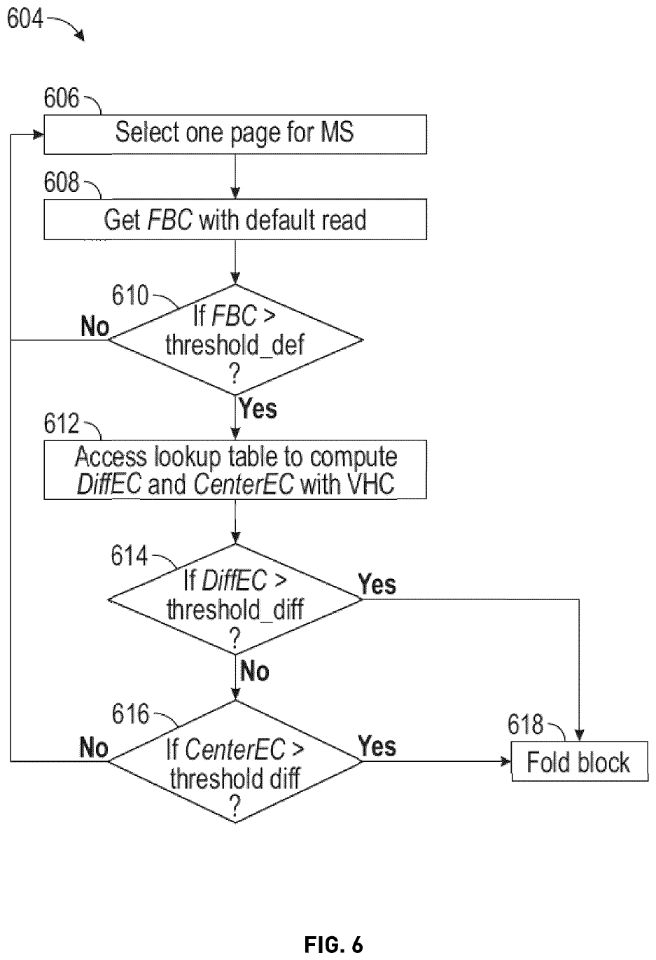

The lookup table 502 enables the second approach (discussed below in connection with FIG. 6) of the adaptive media scan approach, where the AGC offset is adjusted based on the page type and WLG rather than using a fixed offset value. This helps prevent overfolding by accounting for the different valley characteristics observed in different page types and WLGs.

The table's structure allows for efficient lookup during the valley health check process. When a page is being scanned, its page type and WLG can be used to quickly determine the appropriate AGC offset to use when computing the differential error count.

The values in the lookup table 502 have been carefully selected based on observed valley characteristics. For example, the larger offset values for LP pages reflect their wider valleys, while the smaller offsets for UP pages account for their narrower valleys.

FIG. 6 illustrates a routine performed using the media operations manager, in accordance with some examples. Specifically, FIG. 6 illustrates a routine 604 performed by the media operations manager 142 to implement the second approach of the adaptive media scan approach, which uses the lookup table 502 to adjust AGC offsets.

The routine 604 begins at operation 606 where the media operations manager 142 selects a page (or portion of the memory device 130) for a media scan operation. At operation 608, the media operations manager 142 performs a default read to obtain a fail bit count (FBC). At operation 610, the media operations manager 142 determines if the FBC exceeds a threshold value (threshold_def). In response to determining that the FBC exceeds the threshold, the media operations manager 142 performs operation 612; and otherwise the process proceeds to operation 606. At operation 612, the media operations manager 142 accesses the lookup table 502 to obtain the appropriate AGC offset based on the page type and word line group of the portion being scanned. The lookup table 502 contains different predetermined voltage offset values indexed by page type (XP, UP, LP) and word line group (WLG), with the corresponding AGC offset values.

For example, when scanning an extra page (XP) with WLG 0, the lookup table 502 provides an AGC offset of 0. For upper pages (UP) with WLG 0, the lookup table 502 provides an AGC offset of 2. These customized offset values help account for different valley characteristics across page types and WLGs.

Using the retrieved AGC offset, the media operations manager 142 performs the VHC to compute the differential error count (DiffEC) and center error count (CenterEC). At operation 614, the media operations manager 142 checks if the DiffEC exceeds its threshold (threshold_diff). If not, at operation 616, the media operations manager 142 checks if the CenterEC exceeds its threshold (threshold_cen).

If either threshold check (operation 614 and/or operation 616) is satisfied, the routine 604 proceeds to operation 618 to fold the block containing the portion. This approach of using customized AGC offsets from the lookup table helps prevent unnecessary folding of healthy blocks while maintaining reliability through periodic background scanning.

The first and second approaches performed by the media operations manager 142 can be effectively combined to provide more robust protection against unnecessary folding operations. When performing a media scan operation, the media operations manager 142 can first check if the page is in the predetermined weak word line list. For these known weak word lines, the media operations manager 142 bypasses the differential error count threshold check entirely and uses only the center error count threshold to determine folding. For pages not in the weak word line list, the media operations manager 142 then applies the second approach of using customized automatic gain control offsets based on the page type and word line group. The media operations manager 142 accesses the lookup table to obtain the appropriate AGC offset, for example, using an offset of 0 for XP pages with WLG 0, an offset of 6 for XP pages with WLG 1, or an offset of 2 for UP pages.

This combined approach leverages the benefits of both methods while mitigating their individual drawbacks. Together, they provide comprehensive protection against ARC bias-induced overfolding while maintaining reliability through periodic background scanning. The combination is particularly effective because it handles both systematic issues (known weak word lines) and variable characteristics (valley asymmetry across different page types and word line groups). This ensures optimal folding decisions regardless of whether the potential false trigger comes from a known weak word line or from ARC bias in an otherwise healthy block.

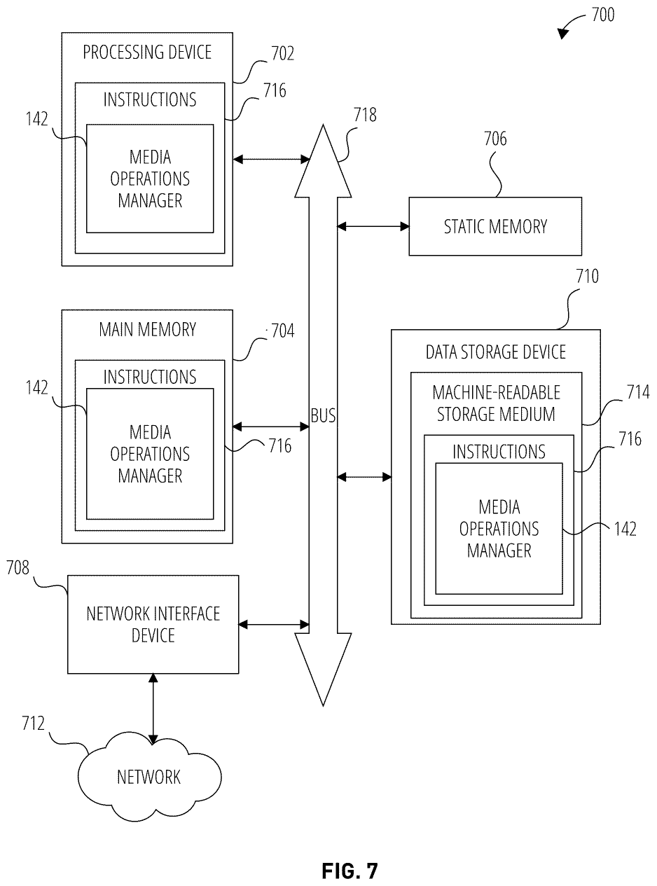

FIG. 7 illustrates an example machine in the form of a computer system 700 within which a set of instructions can be executed for causing the machine to perform any one or more of the methodologies discussed herein. In some examples, the computer system 700 can correspond to a host system (e.g., the host system 120 of FIG. 1) that includes, is coupled to, or utilizes a memory sub-system (e.g., the memory sub-system 110 of FIG. 1) or can be used to perform the operations described herein. In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 700 includes a processing device 702, a main memory 704 (e.g., ROM, flash memory, DRAM such as SDRAM or Rambus DRAM (RDRAM), etc.), a static memory 706 (e.g., flash memory, static random access memory (SRAM), etc.), and a data storage device 710, which communicate with each other via a bus 718.

The processing device 702 represents one or more general-purpose processing devices such as a microprocessor, a central processing unit, or the like. More particularly, the processing device 702 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 702 can also be one or more special-purpose processing devices such as an application-specific integrated circuit (ASIC), a field programmable gate array (FPGA), a digital signal processor (DSP), a network processor, or the like. The processing device 702 is configured to execute instructions 716 for performing the operations and steps discussed herein. The computer system 700 can further include a network interface device 708 to communicate over a network 712.

The data storage device 710 can include a machine-readable storage medium 714 (also known as a computer-readable medium) on which is stored one or more sets of instructions 716 or software embodying any one or more of the methodologies or functions described herein. The instructions 716 can also reside, completely or at least partially, within the main memory 704 and/or within the processing device 702 during execution thereof by the computer system 700, the main memory 704 and the processing device 702 also constituting machine-readable storage media. The machine-readable storage medium 714, data storage device 710, and/or main memory 704 can correspond to the memory sub-system 110 of FIG. 1.

In one example, the instructions 716 include instructions to implement functionality corresponding to providing block failure protection for a zone memory sub-system as described herein. While the machine-readable storage medium 714 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Described implementations of the subject matter can include one or more features, alone or in combination as illustrated below by way of examples.
Example 1. A system comprising: a memory device; and a processing device, operatively coupled to the memory device, programmed to perform operations comprising: performing a media scan operation on a portion of the memory device; determining one or more criteria associated with the portion of the memory device; adjusting one or more folding conditions of the media scan operation based on the one or more criteria associated with the portion of the memory device; and folding the portion of the memory device in response to determining that the adjusted one or more folding conditions are satisfied.
Example 2. The system of Example 1, wherein determining the one or more criteria associated with the portion of the memory device comprises determining that the portion of the memory device comprises one or more word lines (WLs) that are included in a list of predetermined weak WLs.
Example 3. The system of any one of Examples 1-2, wherein determining the one or more criteria associated with the portion of the memory device comprises determining a page type corresponding to the portion of the memory device.
Example 4. The system of any one of Examples 1-3, wherein the operations comprise: performing a default read operation on the portion of the memory device; computing a bit error count (BEC) in response to performing the default read operation; determining that the BEC transgresses a threshold; and performing a valley health check (VHC) in response to determining that the BEC transgresses the threshold.
Example 5. The system of Example 4, wherein performing the VHC comprises: obtaining an automatic read calibration (ARC) offset for reading data from the portion of the memory device; obtaining a predetermined voltage offset for reading data from the portion of the memory device; and computing a differential error count and a center error count for the portion of the memory device based on reading the data from the portion of the memory device one or more times using a voltage computed based on the ARC offset and the predetermined voltage offset.
Example 6. The system of Example 5, wherein the operations for obtaining the ARC offset comprise: generating a plurality of histograms based on reading data from the portion of the memory device; performing a coarse calibration based on the plurality of histograms to obtain a first read level; and performing a fine calibration by: determining a first slope and a second slope based on the first read level; computing a calibration step value based on comparing the first slope and the second slope; and adjusting the first read level by the calibration step value to obtain the ARC offset.
Example 7. The system of any one of Examples 5-6, wherein the differential error count is computed by: obtaining a left error count by reading the portion using a first voltage computed by adding a negative automatic gain control (AGC) offset to the ARC offset; obtaining a right error count by reading the portion using a second voltage computed by adding a positive AGC offset to the ARC offset; and computing an average of the left error count and the right error count to obtain the differential error count.
Example 8. The system of Example 7, wherein the center error count is computed by reading the portion using a third voltage computed based on the ARC offset without applying the predetermined voltage offset.
Example 9. The system of any one of Examples 5-8, wherein adjusting the one or more folding conditions comprises bypassing a first folding condition of the one or more folding conditions that is based on the differential error count in response to determining that the portion of the memory device comprises one or more word lines (WLs) that are included in a list of predetermined weak WLs.
Example 10. The system of Example 9, the operations comprising: selectively folding the portion based on a second folding condition of the one or more folding conditions that is based on a comparison of the center error count to a center threshold value.
Example 11. The system of any one of Examples 5-10, wherein the one or more criteria comprise a page type and a word line group (WLG) of the portion.
Example 12. The system of Example 11, wherein adjusting the one or more folding conditions comprises selecting the predetermined voltage offset used to compute the differential error count based on the page type and WLG of the portion.
Example 13. The system of Example 12, wherein the page type comprises at least one of an extra page (XP), an upper page (UP), or a lower page (LP).
Example 14. The system of any one of Examples 12-13, comprising: storing a lookup table that associates different values for the predetermined voltage offset indexed by page type and WLG.
Example 15. The system of any one of Examples 12-14, wherein the one or more folding conditions comprise comparing the differential error count to a first threshold value and comparing the center error count to a second threshold value.
Example 16. The system of any one of Examples 12-15, wherein folding the portion comprises rewriting data from a block containing the portion to a different block.
Example 17. The system of any one of Examples 1-16, wherein the one or more criteria are determined during a valley health check that measures valley width and valley depth characteristics.
Example 18. The system of any one of Examples 1-17, wherein the memory device comprises a three-dimensional (3D) NAND device.
Example 19. At least one non-transitory machine-readable storage medium comprising instructions that, when executed by a processing device, cause the processing device to perform operations comprising: performing a media scan operation on a portion of a memory device; determining one or more criteria associated with the portion of the memory device; adjusting one or more folding conditions of the media scan operation based on the one or more criteria associated with the portion of the memory device; and folding the portion of the memory device in response to determining that the adjusted one or more folding conditions are satisfied.
Example 20. A method comprising: performing a media scan operation on a portion of a memory device; determining one or more criteria associated with the portion of the memory device; adjusting one or more folding conditions of the media scan operation based on the one or more criteria associated with the portion of the memory device; and folding the portion of the memory device in response to determining that the adjusted one or more folding conditions are satisfied.

The term “coupled with” generally refers to a connection between components, which can be an indirect communicative connection or direct communicative connection (e.g., without intervening components), whether wired or wireless, including connections such as electrical, optical, magnetic, and the like.

“System data” hereinafter refers to data that is created and/or maintained by the memory sub-system for performing operations in response to host requests and for media management.

“User data” hereinafter generally refers to host data and garbage collection data.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (such as a non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine (e.g., a computer) readable storage medium such as a ROM, RAM, magnetic disk storage media, optical storage media, flash memory components, and so forth. A machine-readable storage medium can be non-transitory (in other words, not having any transitory signals) in that it does not embody a propagating signal. However, labeling a machine-readable storage medium “non-transitory” should not be construed to mean that the machine-readable storage medium is incapable of movement; the machine-readable storage medium should be considered as being transportable from one physical location to another.

In the foregoing specification, examples of the disclosure have been described with reference to specific examples thereof. It will be evident that various modifications can be made thereto without departing from the broader scope of examples of the disclosure as set forth in the following claims. The specification and drawings are, accordingly, to be regarded in an illustrative sense rather than a restrictive sense.

What is claimed is:

1. A system comprising:
a memory device; and
a processing device, operatively coupled to the memory device, programmed to perform operations comprising:
performing a media scan operation on a portion of the memory device;
determining one or more criteria associated with the portion of the memory device;
adjusting one or more folding conditions of the media scan operation based on the one or more criteria associated with the portion of the memory device; and
folding the portion of the memory device in response to determining that the adjusted one or more folding conditions are satisfied.

2. The system of claim 1, wherein determining the one or more criteria associated with the portion of the memory device comprises determining that the portion of the memory device comprises one or more word lines (WLs) that are included in a list of predetermined weak WLs.

3. The system of claim 1, wherein determining the one or more criteria associated with the portion of the memory device comprises determining a page type corresponding to the portion of the memory device.

4. The system of claim 1, wherein the operations comprise:
performing a default read operation on the portion of the memory device;
computing a bit error count (BEC) in response to performing the default read operation;
determining that the BEC transgresses a threshold; and
performing a valley health check (VHC) in response to determining that the BEC transgresses the threshold.

5. The system of claim 4, wherein performing the VHC comprises:
obtaining an automatic read calibration (ARC) offset for reading data from the portion of the memory device;
obtaining a predetermined voltage offset for reading data from the portion of the memory device; and
computing a differential error count and a center error count for the portion of the memory device based on reading the data from the portion of the memory device one or more times using a voltage computed based on the ARC offset and the predetermined voltage offset.

6. The system of claim 5, wherein the operations for obtaining the ARC offset comprise:
generating a plurality of histograms based on reading data from the portion of the memory device;
performing a coarse calibration based on the plurality of histograms to obtain a first read level; and
performing a fine calibration by:
determining a first slope and a second slope based on the first read level;
computing a calibration step value based on comparing the first slope and the second slope; and
adjusting the first read level by the calibration step value to obtain the ARC offset.

7. The system of claim 5, wherein the differential error count is computed by:
obtaining a left error count by reading the portion using a first voltage computed by adding a negative automatic gain control (AGC) offset to the ARC offset;
obtaining a right error count by reading the portion using a second voltage computed by adding a positive AGC offset to the ARC offset; and
computing an average of the left error count and the right error count to obtain the differential error count.

8. The system of claim 7, wherein the center error count is computed by reading the portion using a third voltage computed based on the ARC offset without applying the predetermined voltage offset.

9. The system of claim 5, wherein adjusting the one or more folding conditions comprises bypassing a first folding condition of the one or more folding conditions that is based on the differential error count in response to determining that the portion of the memory device comprises one or more word lines (WLs) that are included in a list of predetermined weak WLs.

10. The system of claim 9, the operations comprising:
selectively folding the portion based on a second folding condition of the one or more folding conditions that is based on a comparison of the center error count to a center threshold value.

11. The system of claim 5, wherein the one or more criteria comprise a page type and a word line group (WLG) of the portion.

12. The system of claim 11, wherein adjusting the one or more folding conditions comprises selecting the predetermined voltage offset used to compute the differential error count based on the page type and WLG of the portion.

13. The system of claim 12, wherein the page type comprises at least one of an extra page (XP), an upper page (UP), or a lower page (LP).

14. The system of claim 12, comprising:
storing a lookup table that associates different values for the predetermined voltage offset indexed by page type and WLG.

15. The system of claim 12, wherein the one or more folding conditions comprise comparing the differential error count to a first threshold value and comparing the center error count to a second threshold value.

16. The system of claim 12, wherein folding the portion comprises rewriting data from a block containing the portion to a different block.

17. The system of claim 1, wherein the one or more criteria are determined during a valley health check that measures valley width and valley depth characteristics.

18. The system of claim 1, wherein the memory device comprises a three-dimensional (3D) NAND device.

19. At least one non-transitory machine-readable storage medium comprising instructions that, when executed by a processing device, cause the processing device to perform operations comprising:
performing a media scan operation on a portion of a memory device;
determining one or more criteria associated with the portion of the memory device;
adjusting one or more folding conditions of the media scan operation based on the one or more criteria associated with the portion of the memory device; and
folding the portion of the memory device in response to determining that the adjusted one or more folding conditions are satisfied.

20. A method comprising:
performing a media scan operation on a portion of a memory device;
determining one or more criteria associated with the portion of the memory device;
adjusting one or more folding conditions of the media scan operation based on the one or more criteria associated with the portion of the memory device; and
folding the portion of the memory device in response to determining that the adjusted one or more folding conditions are satisfied.
